(19) United States
(12) Patent Application Publication
(10) Pub. No.: US 2026/0230084 A1
(43) Pub. Date: Aug. 6, 2026

(54) VOLTAGE-TO-TIME CONVERTER IN ANALOG-TO-DIGITAL CONVERTER

(71) Applicant: TAIWAN SEMICONDUCTOR MANUFACTURING COMPANY LTD., HSINCHU (TW)

(72) Inventors: MANOJ BHARAT VASEKAR, HSINCHU CITY (TW); HAMZA YACOUB AL-MAHARMEH, HSINCHU (TW); MEI-CHEN CHUANG, PINGTUNG COUNTY (TW); SHENGGAO LI, Cupertino, CA (US)

(21) Appl. No.: 19/220,136

(22) Filed: May 28, 2025

Related U.S. Application Data
(60) Provisional application No. 63/755,172, filed on Feb. 6, 2025.

(51) Int. Cl. H03M 1/50; H03M 1/12; H03M 1/38

(52) U.S. Cl. CPC H03M 1/50; H03M 1/1255; H03M 1/38

(57) ABSTRACT

A voltage-to-time converter is provided, which includes a first amplifier stage, a second amplifier stage, and an inverter. The first amplifier stage is configured to receive a first input voltage and a second input voltage and generate a first voltage signal with a first slew rate in response to a differential voltage between the first input voltage and the second input voltage. The second input voltage is higher than the first input voltage. The second amplifier stage is coupled to the first amplifier stage and is configured to convert the first voltage signal into a second voltage signal with a second slew rate using a hybrid complementary push-pull structure. The second slew rate is higher than the first slew rate. The inverter is coupled to the second stage and is configured to convert the second voltage signal to generate a time representation signal.

### CROSS-REFERENCE TO RELATED APPLICATION

This application claims the benefit of U.S. Provisional Application No. 63/755,172, filed Feb. 6, 2025, the entire disclosure of which is incorporated by reference herein.

### BACKGROUND

A voltage-to-time converter is an electronic circuit that translates an input voltage level into a proportional time interval, facilitating the measurement of analog signals by converting them into time intervals that can be digitized. Voltage-to-time converters are valued for their simplicity and accuracy, making them suitable for use in time-based analog-to-digital converters (ADCs), frequency modulation, and other signal processing applications where voltage levels need to be accurately represented in the time domain.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 illustrates a block diagram of some embodiments of a hybrid successive-approximation-register analog-to-digital converter (SAR-ADC) in accordance with some embodiments.

FIG. 2 is a block diagram of the hybrid SAR-ADC in accordance with some embodiments.

FIG. 3 is a block diagram of a voltage-to-time converter in accordance with some embodiments.

FIG. 4A is a schematic diagram of a voltage-to-time converter in accordance with some embodiments.

FIG. 4B is a waveform diagram of various signals within the voltage-to-time converter in FIG. 4A.

FIG. 4C is an equivalent circuit diagram of the first stage for small-signal analysis in FIG. 4A.

FIG. 5A is a schematic diagram of a complementary push-pull common source amplifier using a CMOS inverter in accordance with some embodiments.

FIG. 5B is diagram illustrating an equivalent small-signal circuit of the CMOS inverter in FIG. 5A.

FIG. 5C is a diagram illustrating another equivalent small-signal circuit of the CMOS inverter in FIG. 5A.

FIG. 5D is a small-signal circuit diagram of the second stage in the voltage-to-time converter in FIG. 4A.

FIG. 6 is a schematic diagram of a voltage-to-time converter in accordance with some embodiments.

FIG. 7A is a diagram illustrating an equivalent small-signal circuit diagram of the first stage in FIG. 6.

FIG. 7B is a diagram illustrating an equivalent small-signal circuit of the first stage in FIG. 6.

FIG. 7C is a diagram illustrating another equivalent small-signal circuit of the first stage in FIG. 6.

FIG. 7D is a diagram illustrating an equivalent small-signal circuit of the second stage in FIG. 6.

FIG. 8 is flowchart of a method for operating a voltage-to-time converter in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

Successive-approximation-register analog-to-digital converters (SAR-ADCs) are a type of analog-to-digital converter commonly used in integrated chips. An SAR-ADC converts an analog input signal into a digital output signal having a plurality of bits via a binary search algorithm that converges on the analog input signal. Typically, SAR-ADCs may operate by way of a voltage-based signal processing. In voltage-based signal processing, the analog input signal is converted to a voltage, which is compared to a reference voltage to determine a first bit. After determining a first bit, the SAR-ADC moves to a next bit and performs another comparison to an updated reference voltage generated based upon the first bit. The sequence of comparisons continues until an n-bit digital word is generated.

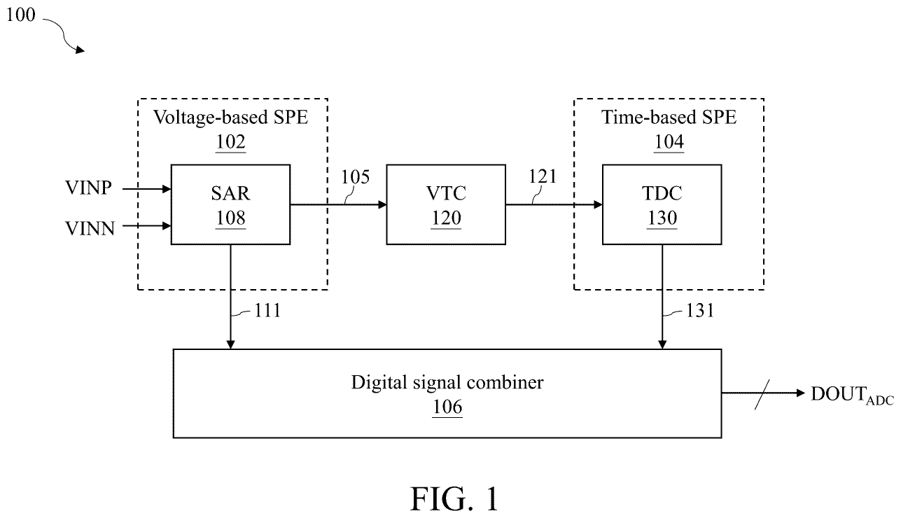

FIG. 1 illustrates a block diagram of some embodiments of a hybrid successive-approximation-register analog-to-digital converter (SAR-ADC) in accordance with some embodiments.

In some embodiments, the hybrid SAR-ADC 100 includes a voltage-based signal processing element (SPE) 102 and a time-based signal processing element (SPE) 104, which are collectively configured to convert voltage signals VINP and VINN (e.g., an analog voltage signal pair) to a digital output signal DOUT_{ADC}. The voltage signals VINP and VINN represent a positive analog input signal and a negative analog input signal, respectively. The voltage-based signal processing element 102 is configured to generate a first digital signal 111 corresponding to a plurality of most significant bits (MSB) of the digital output signal DOUT_{ADC}, while the time-based signal processing element 104 is configured to generate a second digital signal 131 corresponding to a plurality of least significant bits (LSB) of the digital output signal DOUT_{ADC}.

In some embodiments, the voltage-based signal processing element 102 includes a successive-approximation-register (SAR) logic 108. The SAR logic 108 is configured to convert the voltage signals VINP and VINN to the first digital signal 111 using a binary search algorithm. For example, the first digital signal 111 corresponds to the voltage signals VINP and VINN which are used to the plurality of most significant bits (MSB) of the digital output signal DOUT_{ADC}. The SAR logic 108 is also configured to generate a residue voltage 105. The residue voltage 105 corresponds to a differential voltage determined from the voltage signals VINP and VINN and a voltage corresponding to the first digital signal 111.

As the digital values represented by the first digital signal 111 are determined, the voltage converges on the analog input signal pair VINP and VINN, and the residue voltage 105 (i.e., the difference between the input voltage and the reference voltage) decreases. The VTC 120 is configured to generate a time domain representation signal 121 of the residue voltage 105 by performing a voltage-to-time conversion of the residue voltage 105 output from the SAR logic 108. The time domain representation signal 121 comprises a pulse having a width that correspond to the differential voltage of the analog input signal pair VINP and VINN. For example, in some embodiments, a larger residue voltage 105 may cause the time domain representation signal 121 to have a pulse with a greater pulse width than a smaller differential voltage.

The time domain representation signal 121 is provided to the time-based signal processing element 104. In some embodiments, the time-based signal processing element 104 may include a time-to-digital converter (TDC) 130 configured to convert the time domain representation signal 121 to a second digital signal 131. The second digital signal 131 represents digital values for the plurality of least significant bits (LSB) of the digital output signal DOUT_{ADC}.

In some embodiments, the first digital signal 111 and second digital signal 131 are provided to a digital signal combiner 106. The digital signal combiner 106 is a digital output signal generating circuit configured to combine the first digital signal 111 and the second digital signal 131 to generate the digital output signal DOUT_{ADC}. By employing a combination of voltage-based signal processing and time-based signal processing, the hybrid SAR-ADC 100 is able to achieve a low power and a compact area. This is because the time-based signal processing is able to work at low voltages that allow for the overall power of the hybrid SAR-ADC 100 to be low. Furthermore, the hybrid SAR-ADC 100 offers a resolution that improves with deep submicron scaling, so as to provide the hybrid SAR-ADC 100 with scalability benefits over traditional SAR-ADCs.

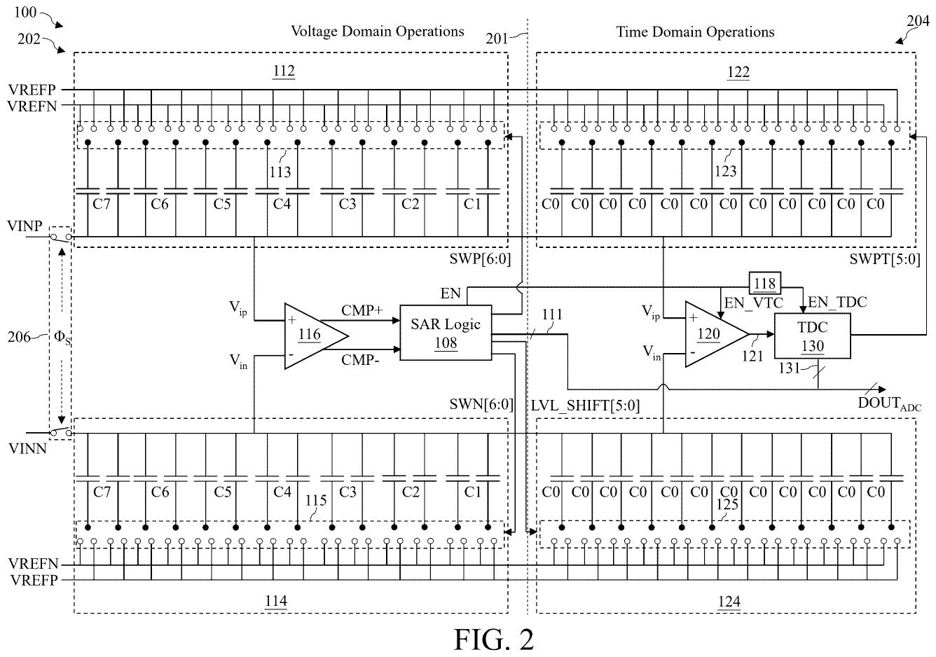

FIG. 2 is a block diagram of the hybrid SAR-ADC in accordance with some embodiments.

In some embodiments, the hybrid SAR-ADC 100 is divided into a first portion 202 and a second portion 204, corresponding to the left and right sides of line 201. The first portion 202 is configured to perform voltage-domain operations, while the second portion 204 is configured to perform time-domain operations. In some embodiments, the first portion 202 may correspond to the voltage-bases SPE 102 shown in FIG. 1, while the second portion 204 may correspond to the time-based SPE 104 and VTC 120 shown in FIG. 1.

The first portion 202 includes capacitors arrays 112 and 114, a comparator 116, and a SAR logic 108. In some embodiments, the capacitor arrays 112 and 114 may be implemented using switch-capacitor arrays, which can be regarded as capacitive ADCs (CDAC). The capacitor array 112 is configured to receive a first analog input voltage signal VINP, a first reference voltage VREFP, and a second reference voltage VREFN, and generate a first voltage signal Vᵢₚ. The capacitor array 114 is configured to receive a second analog input voltage signal VINN, a first reference voltage VREFP, and a second reference voltage VREFN, and generate a second voltage signal Vᵢₙ. In some embodiments, a control circuit 206 is configured to control the first analog input voltage signal VINP and the second analog input voltage signal VINN are controlled using a DAC control signal s, such as sampling values of the first analog input voltage signal VINP and the second analog input voltage signal VINN and hold the sampled values at a constant level for a period of time. In some embodiments, the second reference voltage VREFN may be a ground voltage (GND).

In some embodiments, the first voltage signal Vᵢₚ and the second voltage signal Vᵢₙ are sent to the positive input terminal and the negative input terminal of comparator 116. Comparator 116 is configured to make a comparison to determine whether the first voltage signal Vᵢₚ is greater than or less than the second voltage signal Vᵢₙ to generate comparison signals CMP+ and CMP−, which are sent to the SAR logic 108. The comparison signals CMP+ and CMP− are used to determine a value of a next bit of the first digital signal 111. For example, the SAR logic 108 is configured to adjust a first switch control signal SWP[6:0] and a second switch control signal SWN[6:0] that are used to control switches within the switch array 113 and 115 of the capacitor arrays 112 and 114, respectively. Accordingly, the switches may be switched to connect respective capacitors C1 to C7 to the first reference voltage VREFP or the second reference voltage VREFN, thereby adjusting the voltage residue between the first voltage signal Vᵢₚ and the second voltage signal Vᵢₙ. The SAR logic 108 may perform the aforementioned procedure repeatedly until the MSBs (e.g., DOUT_{SAR}[6:0]) and their sign bit SB within the first digital signal 111 are obtained.

In some embodiments, upon obtaining the first digital signal 111, the SAR logic 108 is further configured to generate an enable signal EN, which serves as an enable signal EN_VTC of the VTC 120. The enable signal EN may passes through a buffer 118 (e.g., a delay circuit) to obtain an enable signal EN_TDC of the TDC 130. Additionally, the SAR logic 108 is further configured to generate a level shift control signal LVL_SHIFT, which is sent to the switch array 125 of the capacitor array 124, thereby controlling the voltage level of the second voltage signal Vᵢₙ.

In some embodiments, when enabled, the VTC 120 is configured to compare the first voltage signal Vᵢₚ and the second voltage signal Vᵢₙ to generate a time domain representation signal 121, which is also represent by a signal VALID. The TDC 130 is configured to generate the second digital signal 131, which corresponds to the LSBs, according to the time domain representation signal 121 generated by the VTC 120. Additionally, the TDC 130 is further configured to generate a third switch control signal SWPT[5:0], which is sent to a switch array 123 of the capacitor array 122.

In some embodiments, the capacitor array 122 includes a plurality of capacitors C0 having substantially equal capacitances, and each capacitor within the capacitor array 122 is electrically connected to the first reference voltage VREFP or the second reference voltage VREFN through the respective switch in the switch array 123, according to the third switch control signal SWPT[5:0], to fine-tune the first voltage signal Vᵢₚ, thereby adjusting the LSBs of the second digital signal 131. Additionally, the capacitor array 124 includes a plurality of capacitors C0 having an equal capacitance, and each capacitor within the capacitor array 124 is electrically connected to the first reference voltage VREFP or the second reference voltage VREFN through the respective switch in the switch array 125, according to the level shift control signal LVL_SHIFT[5:0], to control the voltage level of the second voltage signal Vᵢₙ.

In some embodiments, the capacitor array 112 includes a plurality of capacitor pairs C1 to C7, each being electrically connected to either the first reference voltage VREFP or the second reference voltage VREFN according to the first switch control signal SWP[6:0] generated by the SAR logic 108 while performing the voltage domain operations. Similarly, the capacitor array 114 includes a plurality of capacitor pairs C1 to C7, each being electrically connected to either the first reference voltage VREFP or the second reference voltage VREFN according to the second switch control signal SWN[6:0] generated by the SAR logic 108 while performing voltage domain operations. In some embodiments, the capacitors C1, C2, C3, C4, C5, C6, and C7 may have capacitance values that are twice, four times, six times, ten times, sixteen times, thirty-two times, and fifty-six times that of the capacitor C0 (i.e., C1=2C0, C2=4C0, C3=6C0, C4=10C0, C5=16C0, C6=32C0, and C7=56C0), but the present disclosure is not limited thereto. The capacitance values of the capacitors within the capacitor arrays 112 and 114 can be adjusted according to practical needs.

In some embodiments, the digital signal combiner 106 is configured to combine the first digital signal 111 (e.g., including MSBs represented by DOUT_{SAR}[6:0] and a sign bit SB) and the second digital signal 131 (e.g., including LSBs represented by DOUT_{TDC}[5:0]) to generate a digital output signal DOUT_{AD}c[13:0]. It should be noted that the number of bits in the first digital signal 111, the second digital signal 131, and the digital output signal DOUT_{ADC} are for purposes of description, and they can be adjusted accordingly when using different resolution designs of the hybrid SAR-ADC 100.

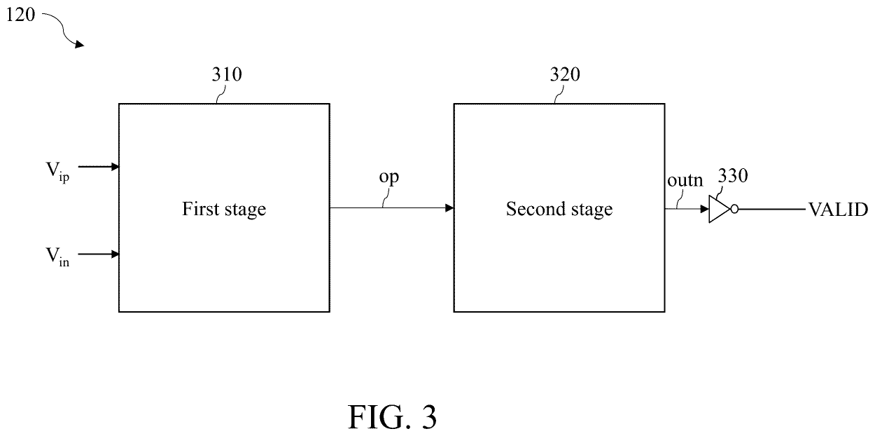

FIG. 3 is a block diagram of a voltage-to-time converter in accordance with some embodiments.

In some embodiments, the voltage-to-time converter 120 includes a first stage 310, a second stage 320, and an inverter 330. The first stage 310 is configured to amplify a differential voltage between the first voltage signal Vᵢₚ and the second voltage signal Vᵢₙ to generate a voltage signal op. The second stage 320 is configured to generate a voltage signal outn based on the voltage signal op generated by the first stage 310. The voltage signal outn passes through the inverter 330 (e.g., a CMOS inverter including an NMOS and a PMOS) to generate a time domain representation signal VALID.

In some embodiments, the first stage 310 is designed to provide an initial gain linearity for the voltage-to-timer converter 120, while the second stage 320 is designed to increase an overall voltage gain of the voltage-to-time converter 120 and a slew rate of the output voltage signal outn. In some embodiments, the first stage 310 may be a pre-amplifier stage implemented by a differential amplifier, while the second stage 320 may be implemented by a complementary push-pull common-source (CS) amplifier with a hybrid structure including a cascode structure of a first first-type transistor and a second first-type transistor, and a parallel structure of a first second-type transistor and a second second-type transistor.

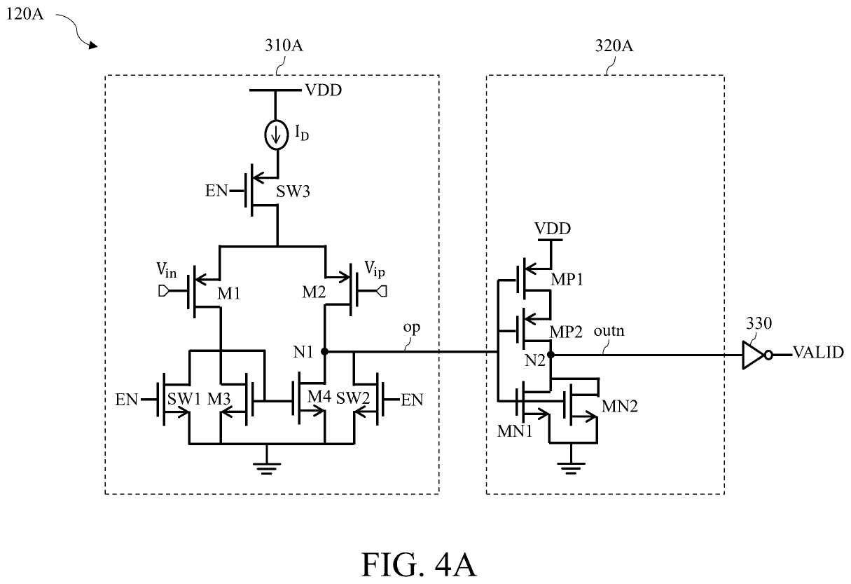

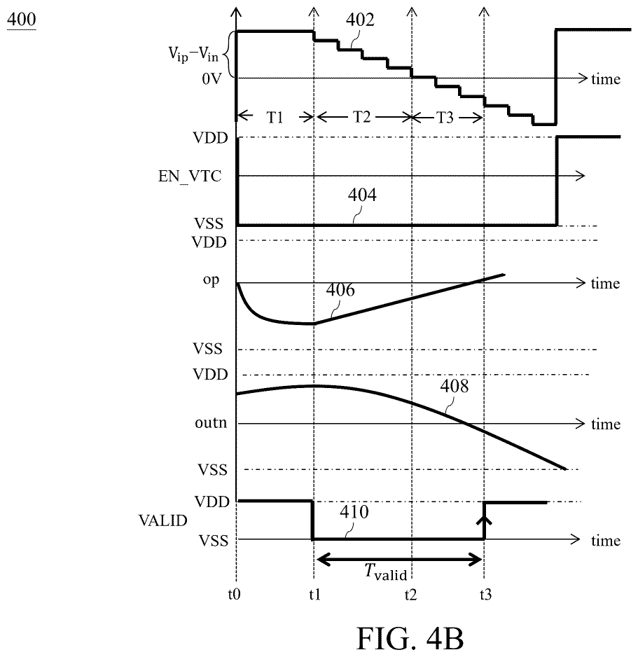

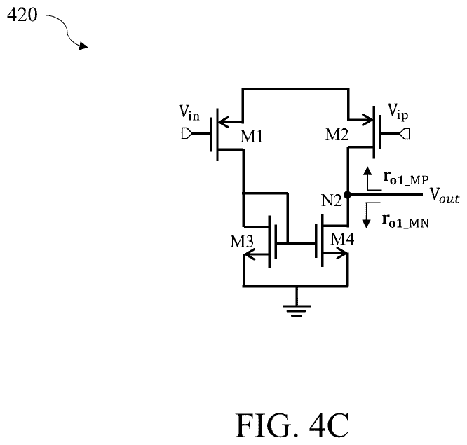

FIG. 4A is a schematic diagram of a voltage-to-time converter in accordance with some embodiments. FIG. 4B is a waveform diagram of various signals within the voltage-to-time converter in FIG. 4A. Please refer to FIGS. 4A and 4B simultaneously.

In some embodiments, the voltage-to-time converter 120 shown in FIGS. 1 to 3 can be implemented using the voltage-to-time converter 120A shown in FIG. 4. The voltage-to-time converter 120A includes a first stage 310A, a second stage 320A, and an inverter 330. The first stage 310A may be implemented by a differential amplifier with a single-ended output (e.g., a non-inverting output). The first stage 310A includes transistors M1 to M4 and switches SW1 to SW3. In some embodiments, transistors M1 and M2 are P-type transistors which form a differential pair. Additionally, transistors M1 and M2 are configured to receive the second voltage signal Vᵢₙ and the first voltage signal Vᵢₚ, respectively. Transistors M3 and M4 are N-type transistors which form a current mirror.

In some embodiments, the switches SW1 to SW3 are controlled by the enable signal EN or EN_VTC generated by the SAR logic 108. The enable signal EN for the voltage-to-time converter 120 may be a low-active signal. While performing the voltage-domain conversion, the SAR logic 108 de-asserts the enable signal EN (e.g., maintain the enable signal EN in a high-logic state (e.g., “1”), such as the time period before time t0 in FIG. 4B. At this time, switches SW1 and SW2 are turned on, and switch SW3 is turned off, disabling the first stage 310A and pulling down the voltage signal op to the ground. Upon completing the voltage-domain operations, the SAR logic 108 asserts the enable signal EN (e.g., maintain the enable signal EN in the low-logic state (e.g., “0”)) at time t0. At this time, switches SW1 and SW2 are turned off, and switch SW3 is turned on, providing the bias current I_{D} to the differential pair (e.g., transistors M1 and M2), thereby amplifying the differential voltage (Vᵢₚ-Vᵢₙ) to obtain the voltage signal op at node N1 (e.g., drain terminal of transistor M2).

In some embodiments, the second stage 320A includes transistors MN1, MN2, MP1, and MP2, which form a complementary push-pull common source amplifier having a hybrid complementary push-pull structure. For example, gate terminals of transistors MN1, MN2, MP1, and MP2 are coupled to node N1, which is an output terminal of the first stage 310A. Transistors MN1 and MN2 are substantially identical, while transistors MP1 and MP2 are substantially identical. A source terminal of transistor MP1 is configured to receive the power supply voltage VDD. A drain terminal of transistor MP1 is coupled to a source terminal of transistor MP2. A drain terminal of transistor MP2 is coupled to node N2, which serves as an output terminal of the second stage 320A. A drain terminal of transistor MN1 is coupled to node N2, and a source terminal of transistor MN1 is coupled to the ground voltage. A drain terminal of transistor MN2 is coupled to node N2, and a source terminal of transistor MN2 is coupled to the ground voltage. Additionally, transistors MN1 and MN2 are arranged in parallel, and transistors MP1 and MP2 are arranged in a cascode structure.

In some embodiments, to improve the voltage pull-down strength of the voltage signal outn in the second stage 320A, transistors MN1 and MN2 can be designed to have a larger size than transistors MP1 and MP2. This ensures that the threshold voltage for the complementary push-pull common source amplifier in the second stage 320A slightly exceeds the settled value of the voltage signal op. In some embodiments, increasing the driving strength of transistors MN1 and MN2 is a design and application specification that depends on the needed gain, output resistance, and power budget. The complementary push-pull circuit design in the second stage 320A provides the designer the flexibility to tune the driving strength as necessary.

In some embodiments, the second stage 320A can be implemented using a complementary metal oxide semiconductor (CMOS) inverter. The threshold voltage of the CMOS inverter is capable of determining the trigger point, which is technology dependent.

In some embodiments, when the voltage-to-time converter 120A is enabled by the enable signal EN, the voltage-to-time converter 120A may enter four phases, such as a level shift phase, a settling phase, a conversion phase, and a decision phase in sequence. For example, during the level shift phase, the differential voltage (Vᵢₚ-Vᵢₙ) received by the first stage 310A is transformed into a single-ended positive voltage to ensure that the first voltage signal Vᵢₚ consistently exceeds the second voltage signal Vᵢₙ by adjusting the second voltage signal Vᵢₙ. For purposes of description, the level shift phase is not shown in the waveform diagram in FIG. 4B, and the level shift phase is completed at time t0. During the settling phase, in response to the voltage level of the voltage signal op falls below the threshold voltage Vₜₕn of transistor MN1 or MN2 by the level shifting at time t1, transistors MN1 and MN2 are turned off, and transistors MP1 and MP2 are turned on, pulling up the voltage level of the voltage signal outn to the power supply voltage VDD (e.g., logic “1”). Thus, the time domain representation signal VALID transitions from the high-logic state (e.g., “1”) to the low-logic state (e.g., “0”) at time t1, as shown by curve 410 in FIG. 4B. The time interval T1 between times t0 and t1 can be referring to as the settling time, which refers to the duration needed for the output voltage (e.g., time domain representation signal VALID) to stabilize within a specified error margin around its final value after a step change is applied to the input voltage (e.g., the input different voltage (Vᵢₚ-Vᵢₙ)).

In some embodiments, the conversion phase refers to the time interval T2 between times t1 and t2. During the conversion phase, the first voltage signal Vᵢₚ decreases in a stepwise or staircase manner, which indicates that the input differential voltage (Vᵢₚ-Vᵢₙ) decreases in a stepwise or staircase manner, as shown by curve 402 in FIG. 4B. Thus, the voltage signal op increases linearly during the conversion phase, as shown by curve 406 in FIG. 4B. Specifically, the voltage-to-time converter 120A acts as a current integrator during the conversion phase, charging the voltage signal op at node N1. Thus, the voltage signal op is then transformed into a rail-to-rail (e.g., ranging from the ground voltage VSS to the power supply voltage VDD) ramp signal through the second stage 320A, which is a complementary push-pull common-source amplifier, resulting in a fast but linear voltage signal outn proportional to the input differential voltage (Vᵢₚ-Vᵢₙ).

In some embodiments, the decision phase refers to the time interval T3 between times t2 and t3. Time interval T3 can also be regarded as the latency of the voltage-to-time converter 120A, which refers to the total time delay from when an input voltage is applied to when the corresponding time-based output is available. During the decision phase, the input differential voltage (Vᵢₚ-Vᵢₙ) is captured into time-based information, thereby completing the voltage-to-time conversion process. Additionally, during the decision phase, when the voltage signal outn goes below the threshold voltage of the inverter 330 at time t3, the time domain representation signal VALID, which is a digital signal, transitions from the low logic state (e.g., “0”) to the high logic state (e.g., “1”).

In some embodiments, during the time interval T_{valid} from time t1 to time t3, the time domain representation signal VALID generated by the voltage-to-time converter 120A is proportional to the input differential voltage (Vᵢₚ-Vᵢₙ) as the voltage domain is converted into the time domain.

FIG. 4C is an equivalent circuit diagram of the first stage for small-signal analysis in FIG. 4A.

In some embodiments, the circuit 420 denotes the equivalent circuit of the first stage 310A during normal operations for small-signal analysis, indicating that switches SW1 to SW3 in FIG. 4A are ignored in FIG. 4C. The input differential voltage Vid of the circuit 420 is (Vᵢₚ-Vᵢₙ). For brevity, gₘ₁ and gₘ₂ are transconductances of transistors M1 and M2, which can be denoted as gₘₚ. Similarly, gₘ₃ and gₘ₄ are transconductances of transistors M3 and M4, which can be denoted as gₘₙ. The differential voltage gain Aᵥ of circuit 420 can be denoted using formula (1) as follows.

$${A}_{v} = \frac{{v}_{out}}{{v}_{id}} = {g}_{mp} ( {r}_{o 1 , MN} ‖ {r}_{o 1 , MP} ) \qquad ( 1 )$$

In formula (1), r_{o1,MP} denotes the output resistance of transistor M2 as viewed from the node N2 (e.g., the output node), while r_{o1,MN} denotes the output resistance of transistor M4 as viewed from the node N2.

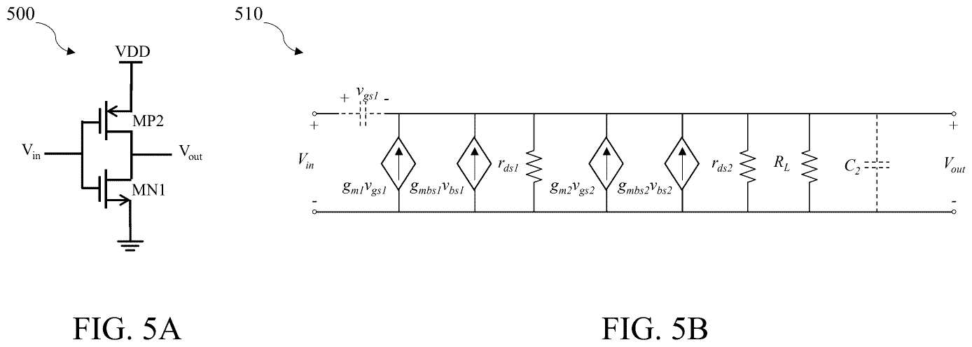

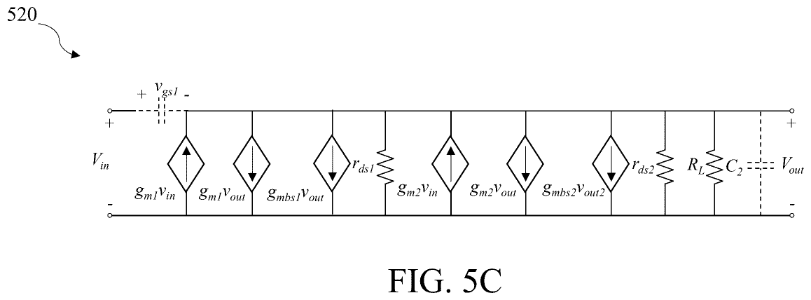

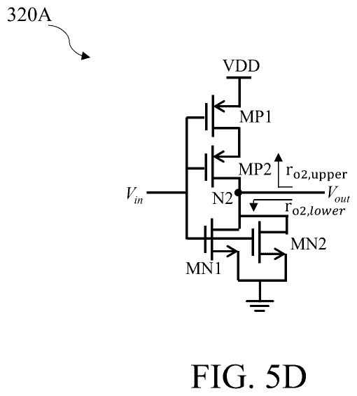

FIG. 5A is a schematic diagram of a complementary push-pull common source amplifier using a CMOS inverter in accordance with some embodiments. FIG. 5B is diagram illustrating an equivalent small-signal circuit of the CMOS inverter in FIG. 5A. FIG. 5C is a diagram illustrating another equivalent small-signal circuit of the CMOS inverter in FIG. 5A. FIG. 5D is a small-signal circuit diagram of the second stage in the voltage-to-time converter in FIG. 4A. Please refer to FIGS. 5A to 5D simultaneously.

For simplicity and purposes of description, the second stage 320A shown in FIG. 4A is simplified to a CMOS inverter 500 shown in FIG. 5A. CMOS inverter 500 includes transistors MN1 and MP2. The bulk of transistor MN1 is coupled to the ground, while the bulk of transistor MP2 is coupled to the power supply voltage VDD. Additionally, it is assumed a load resistance R_{L} and a load capacitance C2 are coupled to the output node N1 of CMOS inverter 500. Accordingly, the small-signal equivalent circuit 510 of CMOS inverter 500 can be expressed by FIG. 5B. The small-signal equivalent circuit 510 shown in FIG. 5B can be redrawn into a small-signal equivalent circuit 520 shown in FIG. 5C.

Thus, the small-signal voltage gain Aᵥ of the CMOS inverter 500 can be expressed using formula (2) as follows.

$$A v = \frac{gm 1 + gm 2}{gds 1 + gds 2 + gm 1 + gmbs 1 + gm 2 + gmbs 2 + {G}_{L}} \qquad ( 2 )$$

In formula (2), G_{L} represents 1/R_{L}, which is ignored in the analysis. gₘ₁ represents the transconductance of transistor MN1, which can be denoted as gₘₙ. Similarly, gₘ₂ represents the transconductance of transistor MP2, which can be denoted as gₘₚ. Additionally, gds1 represent the drain resistance of transistor MN1, which can be expressed as gds1=1/r_{o,MN}. gds2 represent the drain resistance of transistor MP2, which can be expressed as gds2=1l/r_{o,MP}. Furthermore

$${g}_{ds 1} + {g}_{ds 2} = \frac{1}{{r}_{o , MP} ‖ {r}_{o , MN}} .$$

By ignoring the body effect and the output load, the voltage gain Aᵥ can be expressed using formula (3) as follows.

$$A v = \frac{gmn + gmp}{\frac{1}{{r}_{o , MP} ‖ {r}_{o , MN}} + gmn + gmp} = \frac{1}{\frac{1}{( gmn + gmp ) ( {r}_{o , MP} ‖ {r}_{o , MN} )} + 1} \approx \frac{1}{\frac{1}{( gmn + gmp ) ( {r}_{o , MP} ‖ {r}_{o , MN} )}} = ( gmn + gmp ) ( {r}_{o , MP} ‖ {r}_{o , MN} ) \qquad ( 3 )$$

In FIG. 5D, the small-signal schematic diagram of the second stage 320A of the voltage-to-time converter 120A is illustrated. Since transistors MN1 and MN2 are arranged in parallel and transistors MP1 and MP2 are arranged in a cascode structure, the output resistance rout of the second stage 320A can be expressed using formula (4) as follows.

$${r}_{out} \approx {r}_{o 2 , upper} ‖ {r}_{o 2 , lower} = ( {r}_{ds 1 , p} \cdot {r}_{ds 2 , p} ) ‖ ( {r}_{ds 1 , n} ‖ {r}_{ds 2 , n} ) \qquad ( 4 )$$

In formula (4), r_{o2,upper} represents the equivalent output resistance of the upper half of the second stage 320A viewed from the output node N2; r_{o2,lower} represents the equivalent output resistance of the lower half of the second stage 320A viewed from the output node N2. r_{ds1,p} and r_{ds2,p} represent the small-signal drain-to-source resistance of transistors MP1 and MP2, respectively; r_{ds1,n} and r_{ds2,n} represent the small-signal drain-to-source resistance of transistors MN1 and MN2, respectively. Additionally, the overall transconductance for the voltage pull-down path through transistors MN1 and MN2 is 2*gₘₙ. Therefore, the voltage gain AV in formula (3) can be rewritten into formula (5) as follows.

$${A}_{v} = {g}_{m} {r}_{out} = ( 2 \cdot {g}_{mn} + {g}_{mp} ) [ ( {r}_{ds 1 , p} \cdot {r}_{ds 2 , p} ) ‖ ( {r}_{ds 1 , n} ‖ {r}_{ds 2 , n} ) ] \qquad ( 5 )$$

Accordingly, the overall voltage gain A_{VTC} of the voltage-to-time converter 120A can be expressed using formula (6) as follows.

$${A}_{VTC} = ( {g}_{mp} ) \cdot ( {r}_{o 1 , MP} ‖ {r}_{o 1 , MN} ) * ( {g}_{mp} + 2 \cdot {g}_{mn} ) \cdot ( {r}_{o 2 , MP} ‖ {r}_{o 2 , MN} ) \qquad ( 6 )$$

In formula (6), the output resistance r_{o2,MP} is equal to (r_{ds1,p}. r_{ds2,p}), while the output resistance r_{o2,MN} is equal to (r_{ds1,n}∥r_{ds2,n}) or (r_{o1,n}|r_{o2,n}).

In some approaches, a continuous time comparator may function as a voltage-to-time converter, which includes an operational amplifier to serve as the second stage. However, these approaches has a bounded slew rate, an increases latency, and a limited voltage gain due to a low driving current, a high output resistance, and a low overall voltage gain.

In contrast, since the complementary push-pull common source amplifier serves as the second stage 320A, the driving strength of the second stage 320A is increased, indicating a higher driving current flowing through transistors MN1 and MN2 when transistors MN1 and MN2 are turned on. For example, the slew rate SR can be expressed as: SR=I_{on,MN}/Cₒᵤₜₙ, where I_{on,MN} is the turn-on driving current of transistors MN1 and MN2, and Cₒᵤₜₙ is the load capacitance at node N2 (e.g., the output terminal of the second stage 320A). Since transistors MN1 and MN2 are arranged in parallel, the equivalent driving current along the discharge path of the load capacitance Cₒᵤₜₙ through node N2 is twice the driving current of each transistor MN1 and MN2, significantly improving the slew rate of the voltage signal outn at node N2. Additionally, the latency tₚ of the second stage 320A can be expressed as tₚ=a1·R_{on,MN}·Cₒᵤₜₙ, where R_{on,MN} is turn-on resistance of transistors MN1 and MN2, and a1 is a variable corresponding to the input differential voltage, which may be approximately equal to 0.693 in some conditions. This indicates that the latency tₚ of the second stage 320A can be significantly reduced due to the parallel design of transistors MN1 and MN2 in the second stage 320A. Furthermore, the overall voltage gain Av of the voltage-to-time converter 120A significantly improves compared to these approaches due to the increased overall transconductance gₘ=(2·gₘₙ+gₘₚ).

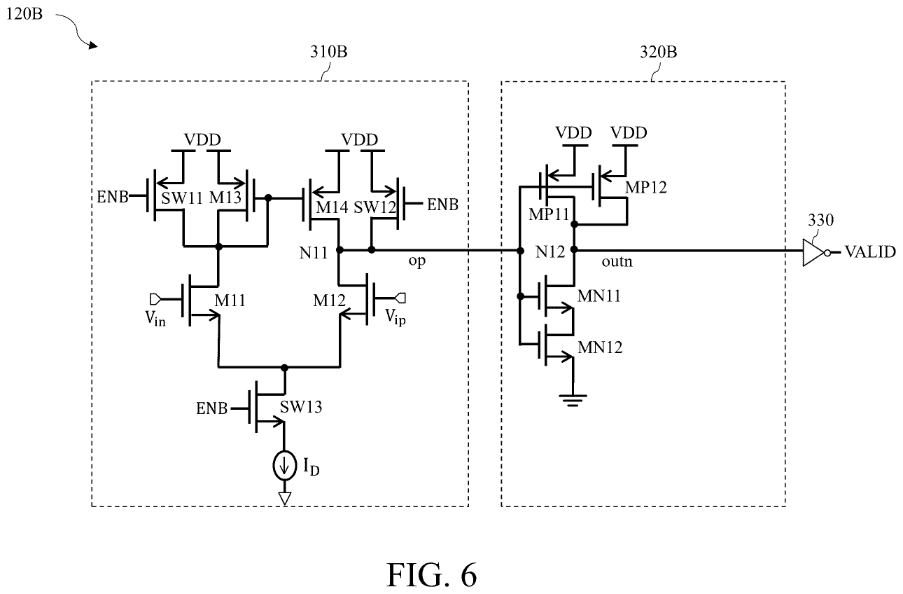

FIG. 6 is a schematic diagram of a voltage-to-time converter in accordance with some embodiments.

In some embodiments, the voltage-to-time converter 120 shown in FIGS. 1 to 3 can be implemented using the voltage-to-time converter 120B shown in FIG. 6. The voltage-to-time converter 120B includes a first stage 310B, a second stage 320B, and an inverter 330. The first stage 310B may be implemented by a differential amplifier with a single-ended output (e.g., a non-inverting output). The first stage 310B includes transistors M11 to M14 and switches SW11 to SW13. In some embodiments, transistors M11 and M12 are N-type transistors which form a differential pair. Additionally, transistors M11 and M12 are configured to receive the second voltage signal Vᵢₙ and the first voltage signal Vᵢₚ, respectively. Transistors M13 and M14 are P-type transistors which form a current mirror.

In some embodiments, the switches SW11 to SW13 are controlled by an enable signal ENB, which is an inverted version of the enable signal EN or EN_VTC generated by the SAR logic 108. The enable signal EN for the voltage-to-time converter 120 may be a low-active signal. While performing the voltage-domain conversion, the SAR logic 108 de-asserts the enable signal EN (e.g., maintain the enable signal EN in a high-logic state (e.g., “1”)), and the enable signal ENB is in the low-logic state (e.g., “0”). At this time, switches SW11 and SW12 are turned on, and switch SW13 is turned off, disabling the first stage 310B and pulling up the voltage signal op to the power supply voltage VDD. Upon completing the voltage-domain operations, the SAR logic 108 asserts the enable signal EN (e.g., maintain the enable signal EN in the low-logic state (e.g., “0”)), and the enable signal ENB is in the high-logic state (e.g., “1”). At this time, switches SW11 and SW12 are turned off, and switch SW13 is turned on, providing the bias current I_{D} to the differential pair (e.g., transistors M11 and M12), thereby amplifying the differential voltage (Vᵢₚ-Vᵢₙ) to obtain the voltage signal op at node N11 (e.g., drain terminal of transistor M12).

In some embodiments, the second stage 320B includes transistors MN11, MN12, MP11, and MP12, which form a complementary push-pull common source amplifier. Transistors MN11 and MN12 are substantially identical, while transistors MP11 and MP12 are substantially identical. For example, gate terminals of transistors MN11, MN12, MP11, and MP12 are coupled to node N11, which is an output terminal of the first stage 310B. A source terminal of transistor MP11 is configured to receive the power supply voltage VDD. A drain terminal of transistor MP11 is coupled to node N12, which serves as an output terminal of the second stage 320B. A source terminal of transistor MP12 is configured to receive the power supply voltage VDD. A drain terminal of transistor MP12 is coupled to node N12. A drain terminal of transistor MN11 is coupled to node N12, and a source terminal of transistor MN11 is coupled to a drain terminal of transistor MN12. A source terminal of transistor MN12 is coupled to the ground voltage. Additionally, transistors MP11 and MP12 are arranged in parallel, and transistors MN11 and MN12 are arranged in a cascode structure.

In some embodiments, to improve the voltage pull-up strength of the voltage signal outn in the second stage 320B, transistors MP11 and MP12 can be designed to have a larger size than transistors MN11 and MN12. This ensures that the threshold voltage for the complementary push-pull common source amplifier in the second stage 320B slightly exceeds the settled value of the voltage signal op. In some embodiments, increasing the driving strength of transistors MP11 and MP12 is a design and application specification that depends on the needed gain, output resistance, and power budget. The complementary push-pull circuit design in the second stage 320B provides the designer the flexibility to tune the driving strength as necessary.

In some embodiments, the second stage 320B can be implemented using a complementary metal oxide semiconductor (CMOS) inverter. The threshold voltage of the CMOS inverter is capable of determining the trigger point, which is technology dependent.

In some embodiments, when the voltage-to-time converter 120B is enabled by the enable signal EN or the enable signal ENB, the voltage-to-time converter 120B may enter four phases, such as a level shift phase, a settling phase, a conversion phase, and a decision phase in sequence. The details thereof are similar to those described in the embodiment of FIG. 4, and thus will not be repeated here.

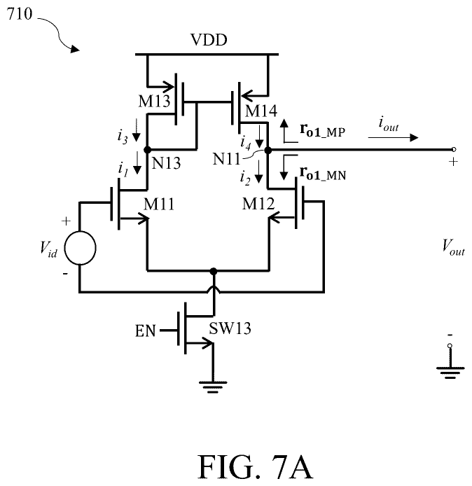

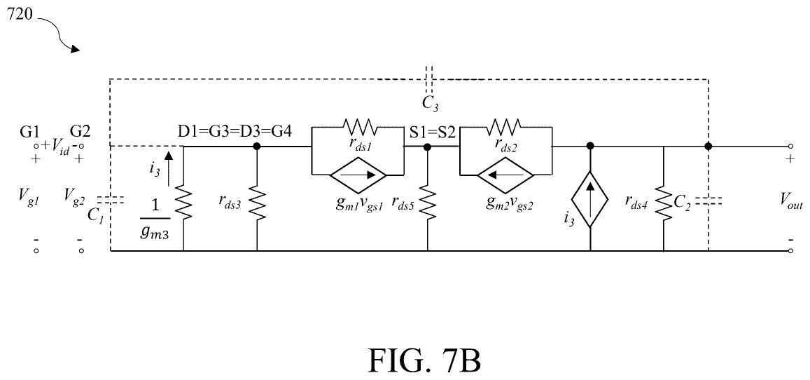

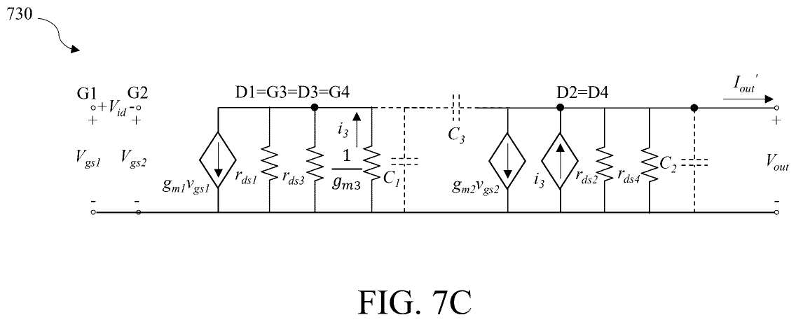

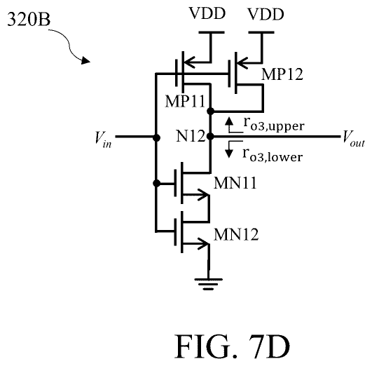

FIG. 7A is a diagram illustrating an equivalent small-signal circuit diagram of the first stage in FIG. 6. FIG. 7B is a diagram illustrating an equivalent small-signal circuit of the first stage in FIG. 6. FIG. 7C is a diagram illustrating another equivalent small-signal circuit of the first stage in FIG. 6.

In some embodiments, the circuit 710 denotes the equivalent circuit of the first stage 310B during normal operations for small-signal analysis, indicating that switches SW11 to SW13 in FIG. 6 are ignored in FIG. 7A. The input differential voltage Vid of the circuit 710 is (Vᵢₚ-Vᵢₙ). For brevity, gₘ₁ and gₘ₂ are transconductances of transistors M11 and M12, which can be denoted as gₘₙ. Similarly, gₘ₃ and gₘ₄ are transconductances of transistors M13 and M14, which can be denoted as gₘₚ. FIG. 7B illustrates the equivalent small-signal circuit 720 of the first stage 310B. For purposes of description, the gate terminal, source terminal, and drain terminal of transistor M11 are denoted as G1, S1, and D1, respectively. The gate terminal, source terminal, and drain terminal of transistor M12 are denoted as G2, S2, and D2, respectively. The gate terminal, source terminal, and drain terminal of transistor M13 are denoted as G3, S3, and D3, respectively. The gate terminal, source terminal, and drain terminal of transistor M14 are denoted as G4, S4, and D4, respectively. Capacitors C1 to C3 may be parasitic capacitances.

The equivalent small-signal circuit 720 in FIG. 7B can be redrawn to the equivalent small-circuit 730 in FIG. 7C. Referring to FIG. 7C, the output current iₒᵤₜ′ can be expressed using formula (7) as follows.

$${i}_{out} = {g}_{m 1} * {g}_{m 3} * {r}_{o , MN 1} ‖ {r}_{o , MP 3} + {g}_{mp 3} * {r}_{o , MN 2} ‖ {r}_{o , MP 4} * {v}_{gs 1} - {g}_{m 2} * {v}_{gs 2} \approx {g}_{mn 1} {v}_{gs 1} - {g}_{mn 2} {v}_{gs 2} = {g}_{mn} {v}_{id} \qquad ( 7 )$$

In formula (7), v_{gs1} and V_{gs2} denote the gate-to-source voltage of transistors M11 and M12, respectively; r_{o,MN1} and r_{o,MP3} denote the output resistance of transistors M11 and M13 viewed from node N13; r_{o,MN2}, and r_{o,MP4} denote the output resistance of transistors M12 and M14 viewed from node N11.

In some embodiments, the output resistance rₒᵤₜ of the first stage 310B can be expressed as

$${r}_{out} = \frac{1}{{g}_{ds 2} + {g}_{ds 4}} = {r}_{o , MN} ‖ {r}_{o , MP} ,$$

where r_{o,MN} and r_{o,MP} denote the output resistances of transistors M12 and M14 viewed from node N11, respectively. Since

$${i}_{out}^{′} = \frac{{v}_{out}}{{r}_{out}} = {g}_{mn} {v}_{id} ,$$

the differential voltage gain Av can be expressed by formula (8) as follows.

$${A}_{v} = \frac{{v}_{out}}{{v}_{id}} = {g}_{mn} ( {r}_{o , MN} ‖ {r}_{o , MP} ) \qquad ( 8 )$$

FIG. 7D is a diagram illustrating an equivalent small-signal circuit of the second stage in FIG. 6.

As described in the embodiment of FIGS. 5A to 5C, the voltage gain Av of a CMOS inverter can be expressed by formula (3): Aᵥ=(gmn+gmp)(r_{o,MP}∥r_{o,MN}). In FIG. 7D, the small-signal schematic diagram of the second stage 320B of the voltage-to-time converter 120B is illustrated. Since transistors MP11 and MP12 are arranged in parallel and transistors MN11 and MN12 are arranged in a cascode structure, the output resistance rout of the second stage 320B can be expressed using formula (9) as follows.

$${r}_{out} \approx {r}_{o 3 , upper} ‖ {r}_{o 3 , lower} = ( {r}_{ds 11 , n} \cdot {r}_{ds 12 , n} ) ‖ ( {r}_{ds 11 , p} ‖ {r}_{ds 12 , p} ) \qquad ( 9 )$$

In formula (4), r_{o3,upper} represents the equivalent output resistance of the upper half of the second stage 320B viewed from the output node N12; r_{o3,lower} represents the equivalent output resistance of the lower half of the second stage 320B viewed from the output node N12. r_{ds11,p} and r_{ds12,p} represent the small-signal drain-to-source resistance of transistors MP11 and MP12, respectively; r_{ds11,n} and r_{ds12,n} represent the small-signal drain-to-source resistance of transistors MN11 and MN12, respectively. Additionally, the overall transconductance for the voltage pull-up path through transistors MP11 and MP12 is 2*gₘₚ. Therefore, the voltage gain AV in formula (3) can be rewritten into formula (10) as follows.

$${A}_{v} = {g}_{m} {r}_{out} = ( 2 \cdot {g}_{mp} + {g}_{mn} ) [ ( {r}_{ds 11 , n} \cdot {r}_{ds 12 , n} ) ‖ ( {r}_{ds 11 , p} ‖ {r}_{ds 12 , p} ) ] \qquad ( 10 )$$

Accordingly, the overall voltage gain A_{VTC} of the voltage-to-time converter 120B can be expressed using formula (11) as follows.

$${A}_{VTC} = ( {g}_{mn} ) \cdot ( {r}_{o 1 , MP} ‖ {r}_{o 1 , MN} ) * ( 2 \cdot {g}_{mp} + {g}_{mn} ) \cdot ( {r}_{o 3 , MP} ‖ {r}_{o 3 , MN} ) \qquad ( 11 )$$

In formula (11), the output resistancer_{o3,MN} is equal to (r_{ds11,n}·r_{ds12,n}); the output resistance r_{o3,MP} is equal to (T_{ds11,p}∥r_{ds12,P}); t_{o1,MP} and r_{o1,MN} denote the output resistance of transistor M14 and M12 viewed from node N11, respectively.

Similar to the voltage-to-time converter 120A in FIG. 4A, the voltage-to-time converter 120B in FIG. 6 also has a high slew rate for the voltage signal outn, a low latency, and a high overall voltage gain, the details of which can be referred to in the embodiment of FIGS. 5A to 5D.

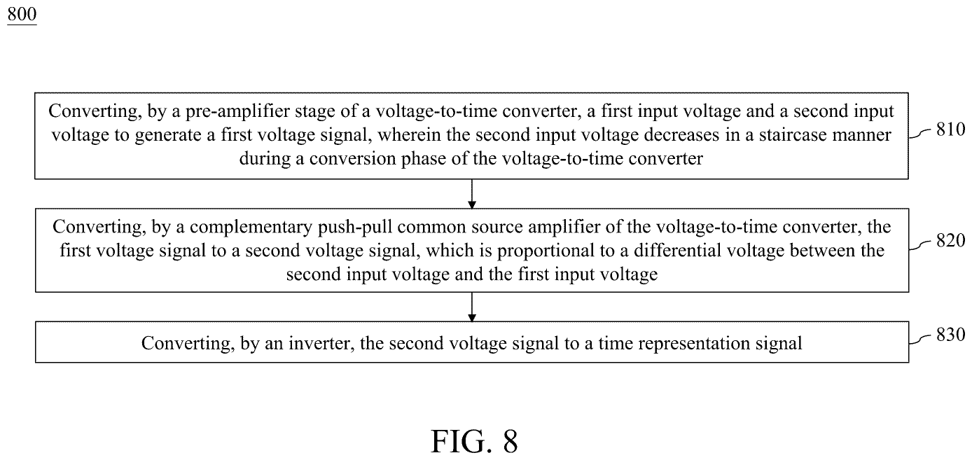

FIG. 8 is flowchart of a method for operating a voltage-to-time converter in accordance with some embodiments. The sequence in which the operations of method 800 are depicted in FIG. 8 is for illustration only; the operations of method 800 are capable of being executed in sequences that differ from that depicted in FIG. 8. It is understood that additional operations may be performed before, during, and/or after the method 800 depicted in FIG. 8, and that some other processes may only be briefly described herein.

In operation 810, a first input voltage and a second input voltage are converted by a pre-amplifier stage of a voltage-to-time converter to generate a first voltage signal, wherein the second input voltage decreases in a staircase manner during a conversion phase of the voltage-to-time converter. In some embodiments, the voltage-to-time converter 120 includes a first stage 310 and a second stage 320, as shown in FIG. 3. The first stage 310, which is a pre-amplifier stage, may be implemented using a differential amplifier. The second stage 320, which is a complementary push-pull common source amplifier, includes a hybrid complementary push-pull structure, such as a first first-type transistor and a second first-type transistor arranged in a parallel structure, and a second second-type transistor and a second second-type transistor arranged in a cascode structure.

In operation 820, the first voltage signal is converted, by a complementary push-pull common source amplifier of the voltage-to-time converter, to a second voltage signal, which is proportional to a differential voltage between the second input voltage and the first input voltage. In some embodiments, the slew rate of the second voltage signal (e.g., outn) generated by the complementary push-pull common source amplifier is higher than that of the first voltage signal (e.g., op).

In operation 830, the second voltage signal is converted, by an inverter, to a time representation signal. In some embodiments, the time representation signal (e.g., VALID) may be asserted (e.g., in the low logic state) during the conversion phase and the decision phase of the voltage-to-time converter, such as time intervals T2 and T3 shown in FIG. 4B.

An aspect of the present disclosure provides a voltage-to-time converter which includes a first amplifier stage, a second amplifier stage, and an inverter. The first amplifier stage is configured to receive a first input voltage and a second input voltage and generate a first voltage signal with a first slew rate in response to a differential voltage between the first input voltage and the second input voltage. The second input voltage is higher than the first input voltage. The second amplifier stage is coupled to the first amplifier stage and is configured to convert the first voltage signal into a second voltage signal with a second slew rate using a hybrid complementary push-pull structure. The second slew rate is higher than the first slew rate. The inverter is coupled to the second amplifier stage and is configured to convert the second voltage signal to generate a time representation signal.

Another aspect of the present disclosure provides a voltage-to-time converter which includes a first amplifier stage, a second amplifier stage, and an inverter. The first amplifier stage is configured to receive an input differential voltage and generate a first voltage signal in response to the input differential voltage, which decreases in a stepwise manner during a conversion phase of the voltage-to-time converter. The second amplifier stage is coupled to the first amplifier stage and is configured to convert the first voltage signal into a second voltage signal, which is proportional to the differential voltage, using a hybrid complementary push-pull structure. The inverter is coupled to the second amplifier stage and is configured to convert the second voltage signal to generate a time representation signal.

Yet another aspect of the present disclosure provides a method. A first input voltage and a second input voltage are converted by a pre-amplifier stage of a voltage-to-time converter to generate a first voltage signal, wherein the second input voltage decreases in a staircase manner during a conversion phase of the voltage-to-time converter. The first voltage signal is converted, by a complementary push-pull common source amplifier of the voltage-to-time converter, to a second voltage signal, which is proportional to a differential voltage between the second input voltage and the first input voltage. The second voltage signal is converted, by an inverter, to a time representation signal.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A voltage-to-time converter, comprising:
a first amplifier stage, configured to receive a first input voltage and a second input voltage, and generate a first voltage signal with a first slew rate in response to a differential voltage between to the first input voltage and the second input voltage, wherein the second input voltage is higher than the first input voltage;
a second amplifier stage, coupled to the first amplifier stage, and configured to convert the first voltage signal into a second voltage signal with a second slew rate using a hybrid complementary push-pull structure, wherein the second slew rate is higher than the first slew rate; and
an inverter, coupled to the second amplifier stage, and configured to convert the second voltage signal to generate a time representation signal.

2. The voltage-to-time converter of claim 1, wherein the first amplifier stage comprises a differential amplifier, and the second amplifier stage comprises a complementary push-pull common source amplifier.

3. The voltage-to-time converter of claim 2, wherein the first amplifier stage provides a first voltage gain with respect to the differential voltage, and the second amplifier stage provides a second voltage gain with respect to the first voltage signal generated at a non-inverting output terminal of the first amplifier stage.

4. The voltage-to-time converter of claim 3, wherein the hybrid complementary push-pull structure comprises:
a first first-type transistor and a second first-type transistor arranged in parallel,
a first second-type transistor and a second second-type transistor arranged in a cascode structure, wherein the cascode structure are electrically connected to the first first-type transistor and the second first-type transistor.

5. The voltage-to-time converter of claim 4, wherein a size of the first first-type transistor and the second first-type transistor is greater than that of the first second-type transistor and the second second-type transistor.

6. The voltage-to-time converter of claim 4, wherein during a settling phase of the voltage-to-time converter, the first voltage signal generated by the first amplifier stage decreases until the first voltage signal falls below a first threshold voltage of the first first-type transistor and the second first-type transistor.

7. The voltage-to-time converter of claim 6, wherein in response to the first voltage signal falling below the first threshold voltage of the first first-type transistor and the second first-type transistor, the first second-type transistor and the second second-type transistor are activated, pulling up the second voltage signal to a high logic state and pulling down the time representation signal to a low logic state.

8. The voltage-to-time converter of claim 7, wherein during a conversion phase of the voltage-to-time converter, the second input voltage decreases in a stepwise manner, the first voltage signal generated by the first amplifier stage increases linearly, and the second voltage signal generated by the second amplifier stage is a rail-to-rail ramp signal ranging from a ground voltage to a power supply voltage.

9. The voltage-to-time converter of claim 8, wherein the second voltage signal is proportional to the differential voltage between the first input voltage and the second input voltage.

10. The voltage-to-time converter of claim 8, wherein during a decision phase of the voltage-to-time converter, upon the second voltage signal generated by the second amplifier stage being lower than a second threshold voltage of the inverter, the time representation signal generated by the inverter transitions from the low logic state to the high logic state.

11. The voltage-to-time converter of claim 10, wherein a latency of the voltage-to-time converter comprises a first duration of the conversion phase and a second duration of the decision phase.

12. The voltage-to-time converter of claim 4, wherein the first amplifier stage comprises a third second-type transistor and a fourth second-type transistor which form a differential pair, and a first transconductance of the first amplifier stage equals to a transconductance of the fourth second-type transistor.

13. The voltage-to-time converter of claim 12, wherein a second transconductance of the second amplifier stage equals to a transconductance of the second second-type transistor plus twice a transconductance of the first first-type transistor.

14. A voltage-to-time converter, comprising:
a first amplifier stage, configured to receive an input differential voltage, and generate a first voltage signal in response to the input differential voltage, which decreases in a stepwise manner during a conversion phase of the voltage-to-time converter;
a second amplifier stage, coupled to the first amplifier stage, and configured to convert the first voltage signal into a second voltage signal, which is proportional to the input differential voltage, using a hybrid complementary push-pull structure; and
an inverter, coupled to the second amplifier stage, and configured to convert the second voltage signal to generate a time representation signal.

15. The voltage-to-time converter of claim 14, wherein the first amplifier stage comprises a differential amplifier, and the second amplifier stage comprises a complementary push-pull common source amplifier.

16. The voltage-to-time converter of claim 14, wherein a second slew rate of the second voltage signal is higher than a first slew rate of the first voltage signal.

17. The voltage-to-time converter of claim 14, the hybrid complementary push-pull structure comprises:
a first first-type transistor and a second first-type transistor arranged in parallel, a first second-type transistor and a second second-type transistor arranged in a cascode structure, wherein the cascode structure are electrically connected to the first first-type transistor and the second first-type transistor.

18. The voltage-to-time converter of claim 17, wherein a transconductance of the second amplifier stage equals to a transconductance of the second second-type transistor plus twice a transconductance of the first first-type transistor.

19. A method, comprising:
converting, by a pre-amplifier stage of a voltage-to-time converter, a first input voltage and a second input voltage to generate a first voltage signal, wherein the second input voltage decreases in a staircase manner during a conversion phase of the voltage-to-time converter; and
converting, by a complementary push-pull common source amplifier of the voltage-to-time converter, the first voltage signal to a second voltage signal, which is proportional to a differential voltage between the second input voltage and the first input voltage; and
converting, by an inverter, the second voltage signal to a time representation signal.

20. The method of claim 19, wherein a slew rate of the second voltage signal is higher than that of the first voltage signal.
